(19) United States
(12) Patent Application Publication
(10) Pub. No.: US 2026/0033377 A1
(43) Pub. Date: Jan. 29, 2026

(54) SEMICONDUCTOR DEVICE AND METHOD OF MANUFACTURING THE SAME

(71) Applicant: FUJI ELECTRIC CO., LTD., Kawasaki-shi (JP)

(72) Inventor: Hijiri TANAKA, Matsumoto-city (JP)

(73) Assignee: FUJI ELECTRIC CO., LTD., Kawasaki-shi (JP)

(21) Appl. No.: 19/219,830

(22) Filed: May 27, 2025

(30) Foreign Application Priority Data
Jul. 26, 2024 (JP) 2024-121300

(51) Int. Cl. H01L 23/31; H01L 21/56; H01L 23/367

(52) U.S. Cl. CPC H01L 23/3107; H01L 21/565; H01L 23/367

(57) ABSTRACT

A semiconductor device, including: a board having an upper surface, a lower surface, and a side surface; and a sealing member having a lower surface and an opening in the lower surface thereof, the opening having an inclined side surface therein, the sealing member sealing the upper surface and the side surface of the board, leaving the entire lower surface of the board exposed from the opening, so as to form: an under-board space directly below the lower surface of the board, and a lateral space directly below the inclined side surface of the opening, and continuous with the under-board space.

### CROSS-REFERENCE TO RELATED APPLICATION

This application is based upon and claims the benefit of priority of the prior Japanese Patent Application No. 2024-121300, filed on Jul. 26, 2024, the entire contents of which are incorporated herein by reference.

### BACKGROUND OF THE INVENTION

### 1. Field of the Invention

The embodiments discussed herein relate to a semiconductor device and a method of manufacturing the same.

### 2. Background of the Related Art

A semiconductor device includes a semiconductor module and a cooling module provided on the semiconductor module via a thermally conductive bonding member (see, for example, Japanese Laid-open Patent Publication No. 2012-033872, Japanese Laid-open Patent Publication No. 2013-065648, International Publication Pamphlet No. WO 2013/099545, and International Publication Pamphlet No. WO 2019/239997)

### SUMMARY OF THE INVENTION

According to one aspect, there is provided a semiconductor device, including: a board having an upper surface, a lower surface, and a side surface; and a sealing member having a lower surface and an opening in the lower surface thereof, the opening having an inclined side surface therein, the sealing member sealing the upper surface and the side surface of the board, leaving the entire lower surface of the board exposed from the opening, so as to form an under-board space directly below the lower surface of the board, and a lateral space directly below the inclined side surface of the opening, and continuous with the under-board space.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a side view of a semiconductor device according to a first embodiment;

FIG. 2 is a first sectional view of the semiconductor device according to the first embodiment;

FIG. 3 is a second sectional view of the semiconductor device according to the first embodiment;

FIG. 4 is an enlarged view of a first cross section of the semiconductor device according to the first embodiment;

FIG. 5 is a flowchart illustrating a semiconductor device manufacturing method according to the first embodiment;

FIG. 6 is a first view for describing a semiconductor unit assembling step of the semiconductor device manufacturing method according to the first embodiment;

FIG. 7 is a second view for describing the semiconductor unit assembling step of the semiconductor device manufacturing method according to the first embodiment;

FIG. 8 is a first view for describing a sealing step of the semiconductor device manufacturing method according to the first embodiment;

FIG. 9 illustrates a storage mold used in the sealing step of the semiconductor device manufacturing method according to the first embodiment;

FIG. 10 is a perspective view of the storage mold used in the sealing step of the semiconductor device manufacturing method according to the first embodiment;

FIG. 11 is a second view for describing the sealing step of the semiconductor device manufacturing method according to the first embodiment;

FIG. 12 is a third view for describing the sealing step of the semiconductor device manufacturing method according to the first embodiment;

FIG. 13 is a fourth view for describing the sealing step of the semiconductor device manufacturing method according to the first embodiment;

FIG. 14 is a view for describing an attachment step of the semiconductor device manufacturing method according to the first embodiment;

FIG. 15 is an enlarged view of a first cross section of a semiconductor device according to a second embodiment;

FIG. 16 is a second sectional view of a semiconductor device according to a third embodiment; and

FIG. 17 is a third sectional view of the semiconductor device according to the third embodiment.

### DETAILED DESCRIPTION OF THE INVENTION

Hereinafter, embodiments will be described with reference to the drawings. In the following description, a “front surface” and an “upper surface” represent an X-Y plane facing upward (+Z direction) in a semiconductor device 1 in the drawings. Similarly, the term “up” indicates an upward direction (+Z direction) in the semiconductor device 1 of the drawings. A “rear surface” and a “lower surface” represent an X-Y plane facing downward (−Z direction) in the semiconductor device 1 of the drawings. Similarly, the term “down” indicates a downward direction (−Z direction) in the semiconductor device 1 of the drawings. The same directionality as described above applies to all the drawings, where applicable. The terms “higher” and “above” indicate positions on the upper side (+Z direction) in the semiconductor device 1 of the drawings. Similarly, the terms “lower” and “below” represent positions on the lower side (−Z direction) in the semiconductor device 1 of the drawings. The terms “front surface”, “upper surface”, “up” and “rear surface”, “lower surface”, “down”, and “side surface” are merely expressions for convenience of specifying relative positional relationship, and do not limit the technical ideas of the embodiments. For example, “up” and “down” do not always mean the vertical directions with respect to the ground. That is, the “up” and “down” directions are not limited to the gravity direction. In addition, in the following description, a “main component” represents a component contained at 80% or more by volume. Further, the expression “substantially the same” may allow an error range of ±10%. In addition, the expressions “being perpendicular”, “being orthogonal”, and “being parallel” may allow an error range of ±10°. In addition, once a reference numeral is given to a component in a drawing, the reference numeral may be omitted in the subsequent drawings.

### First Embodiment

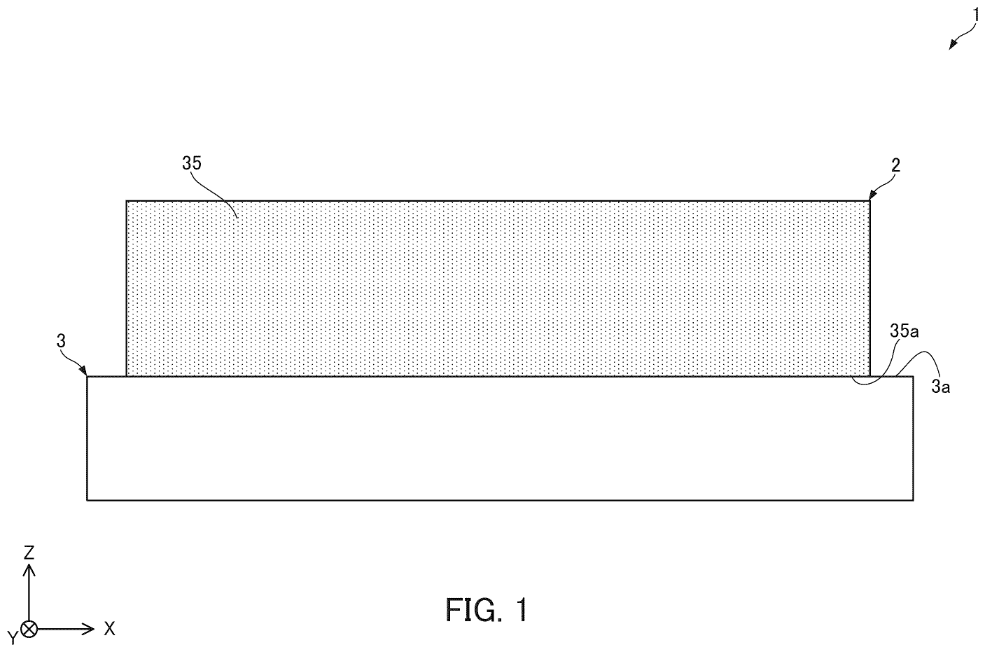

A semiconductor device 1 according to a first embodiment will be described with reference to FIG. 1. FIG. 1 is a side view of the semiconductor device according to the first embodiment. The semiconductor device 1 includes a semiconductor module 2 and a cooling module 3. The semiconductor device 1 may include requisite components in addition to these components.

The components of the semiconductor module 2 are sealed by a sealing member 35. That is, the sealing member 35 forms the outer periphery of the semiconductor module 2. The outer periphery of the semiconductor module 2 has, for example, a rectangular parallelepiped shape. The semiconductor module 2 (sealing member 35) includes a lower surface 35a (second lower surface). The sealing member 35 will be described in detail later.

The cooling module 3 includes, on its upper surface, a cooling surface 3a on which the lower surface 35a of the semiconductor module 2 is disposed. The cooling surface 3a is larger than the lower surface 35a of the semiconductor module 2 and is flat. The cooling module 3 may be, for example, a heat dissipation base including heat dissipation fins or a cooling device in which a refrigerant circulates.

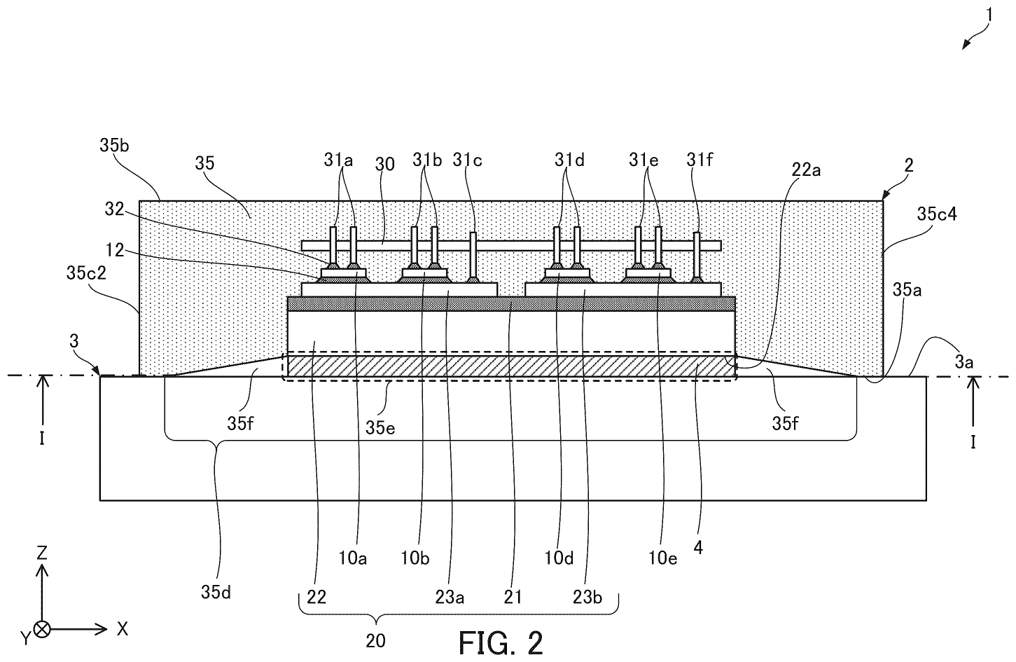

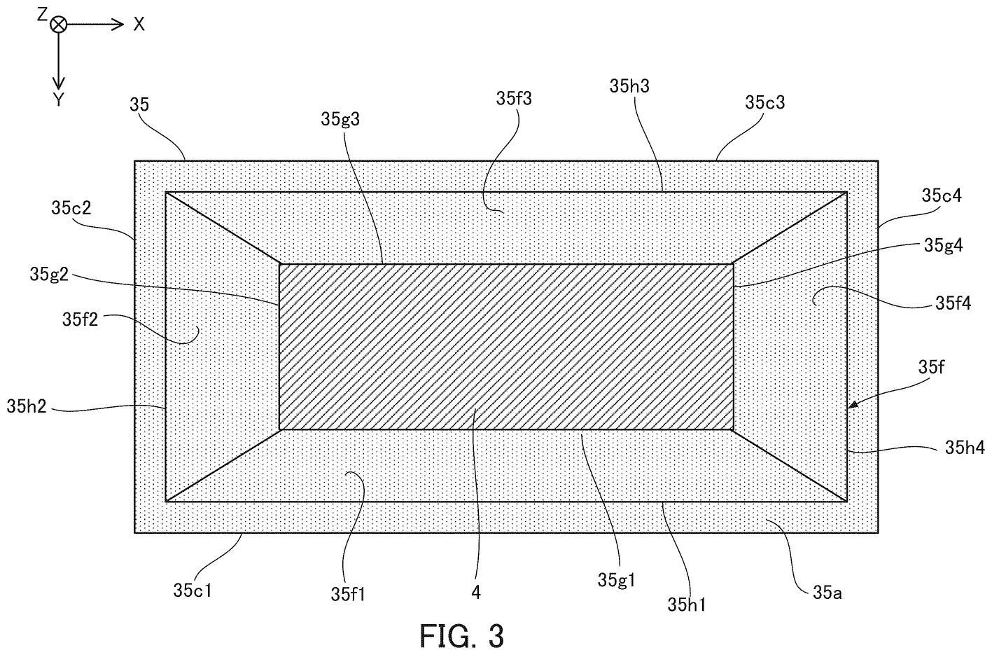

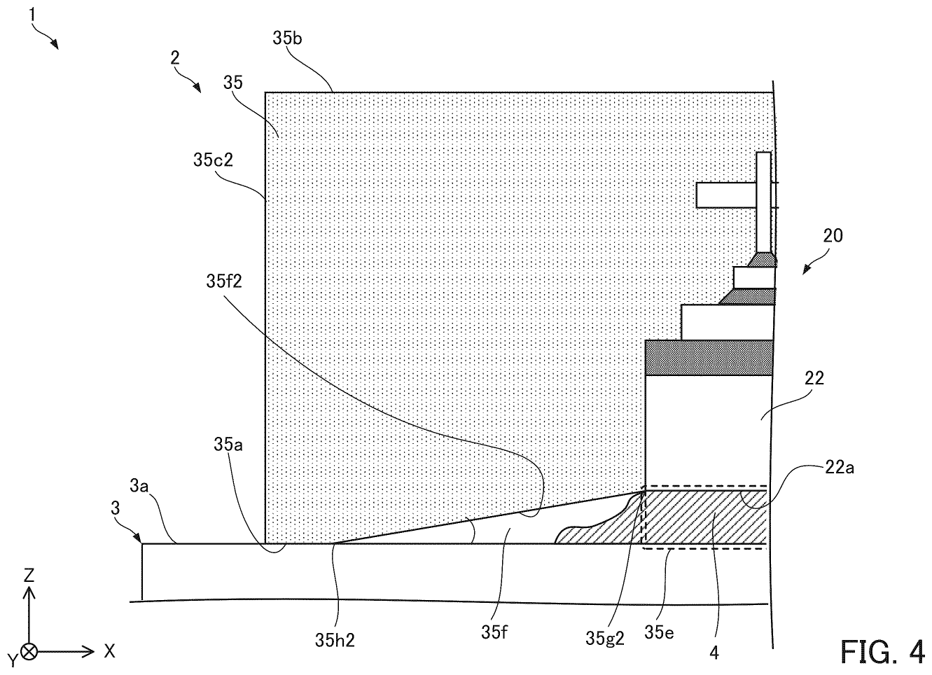

Next, details of the semiconductor module 2 will be described with reference to FIGS. 2 to 4. FIG. 2 is a first sectional view of the semiconductor device according to the first embodiment. FIG. 3 is a second sectional view of the semiconductor device according to the first embodiment. FIG. 4 is an enlarged view of a first cross section of the semiconductor device according to the first embodiment. FIG. 2 is a sectional view taken along the Z-X plane passing through the center in the ±Y direction and viewed in the +Y direction in FIG. 1. FIG. 3 is a sectional view taken along a dashed-dotted line I-I in FIG. 2 (a rear view of the semiconductor module 2). FIG. 4 is an enlarged view of a lateral space 35f and its surrounding area of FIG. 2. FIGS. 2 and 3 depict a case where an adhesive member 4 is applied to the entire lower surface 22a of an insulated circuit board 20 of the semiconductor module 2.

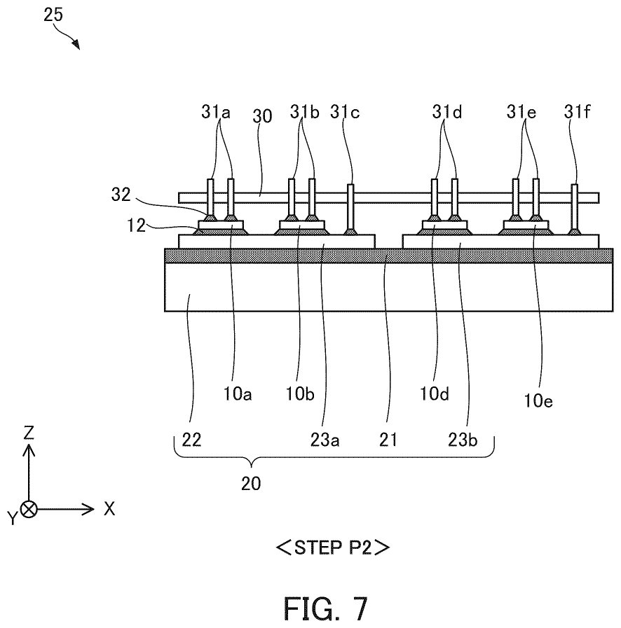

As described above, the semiconductor device 1 includes the semiconductor module 2 and the cooling module 3. The semiconductor module 2 and the cooling module 3 are joined by the adhesive member 4. In the semiconductor module 2, semiconductor chips 10a, 10b, 10d, and 10e, the insulated circuit board 20, and the printed board 30 are sealed by the sealing member 35. In the semiconductor module 2, a structure excluding the sealing member 35 is referred to as a semiconductor unit 25 (see FIG. 7). That is, the semiconductor unit 25 includes the semiconductor chips 10a, 10b, 10d, and 10e, the insulated circuit board 20, and the printed board 30. In the semiconductor module 2, the semiconductor unit 25 is sealed by the sealing member 35. The semiconductor unit 25 may be provided with a main current terminal and a control terminal (not illustrated). The main current terminal and the control terminal may extend to the outside of the sealing member 35.

The semiconductor chips 10a, 10b, 10d, and 10e may be power metal-oxide-semiconductor field-effect transistors (MOSFETs) made mainly of silicon carbide. In the power MOSFET, the body diode may function as a freewheeling diode (FWD). Each of the semiconductor chips 10a, 10b, 10d, and 10e includes, for example, an input electrode (drain electrode) as a main electrode on the lower surface, and an output electrode (source electrode) as a main electrode and a control electrode (gate electrode) on the upper surface. The control electrode may be provided at the center of one side portion of the upper surface of each of the semiconductor chips 10a, 10b, 10d, and 10e or at a position shifted from the center along the side portion.

Alternatively, the semiconductor chips 10a, 10b, 10d, and 10e may each include a switching element made mainly of silicon. The switching element is, for example, a reverse-conducting-insulated gate bipolar transistor (RC-IGBT). The RC-IGBT is a semiconductor element in which an IGBT and an FWD are configured in inverse-parallel in one chip. Each of the semiconductor chips 10a, 10b, 10d, and 10e includes an input electrode (collector electrode), which is a main electrode, on the lower surface, and an output electrode (emitter electrode), which is a main electrode, and a control electrode (gate electrode) on the upper surface. As in the case of the power MOSFET, the control electrode may be provided at the center of one side portion of the upper surface of each of the semiconductor chips 10a, 10b, 10d, and 10e or at a position shifted from the center along the side portion.

Further, for example, the semiconductor chips 10a, 10b, 10d, and 10e may be semiconductor chips that are made mainly of silicon. Specifically, the semiconductor chips 10a and 10d may be switching elements, and the semiconductor chips 10b and 10e may be diode elements. The switching element is, for example, a power MOSFET or an IGBT. A semiconductor chip including a switching element includes, for example, an input electrode (a drain electrode in a power MOSFET and a collector electrode in an IGBT) as a main electrode on the lower surface, and a gate electrode as a control electrode and an output electrode (a source electrode in a power MOSFET and an emitter electrode in an IGBT) as a main electrode on the upper surface. In the diode element, for example, a Schottky barrier diode (SBD) or a P-intrinsic-N (PiN) diode is used as the FWD. A semiconductor chip including a diode element includes an output electrode (cathode electrode) as a main electrode on the lower surface and an input electrode (anode electrode) as a main electrode on the upper surface.

The semiconductor chips 10a and 10b and the semiconductor chips 10d and 10e are bonded, respectively, to conductive patterns 23a and 23b, which will be described later, by solder 12. The solder 12 is made of a solder component. The solder component is a substance constituting the solder 12 and includes a lead-free solder containing a predetermined alloy as a main component. The predetermined alloy contains tin. Such an alloy is, for example, at least one of an alloy of tin-silver, an alloy of tin-silver-copper, an alloy of tin-zinc-bismuth, an alloy of tin-copper, an alloy of tin-silver-indium-bismuth, and an alloy of tin-antimony. Furthermore, the solder component may contain an additive. Examples of the additive include nickel, germanium, cobalt, and silicon. Therefore, as an example, the solder component contains tin and at least one of silver, zinc, copper, bismuth, indium, and antimony. Further, the solder component may contain, for example, at least one of nickel, germanium, cobalt, and silicon. The solder component of solder 32 described later is the same as that of the solder 12. A sintered body may be used instead of the solder 12. The sintered material in the case of bonding by a sintered body is, for example, powder of silver, iron, copper, aluminum, titanium, nickel, tungsten, or molybdenum.

The insulated circuit board 20 is an example of a substrate, and includes an insulating plate 21, a metal plate 22, and the conductive patterns 23a and 23b. The insulating plate 21 and the metal plate 22 have a rectangular shape in plan view. Corner portions of the insulating plate 21 and the metal plate 22 may be R-chamfered or C-chamfered. In plan view, the size of the metal plate 22 may be smaller than the size of the insulating plate 21, and the metal plate 22 may be formed inside the insulating plate 21. The upper surface of the insulated circuit board 20 may refer to the area that is visible in a plan view of the insulated circuit board 20. Specifically, it includes the upper surfaces of the conductive patterns 23a and 23b described later and the upper surface of the insulating plate 21 excluding a region where the conductive patterns 23a and 23b are disposed. The side surfaces of the insulated circuit board 20 may refer to the areas that are visible from each of the four sides of the insulated circuit board 20 in a side view. Specifically, the side surfaces include the side surfaces at the four sides of the insulating plate 21 described later, the side surfaces at the four sides of the metal plate 22, and the side surfaces at the four sides of the conductive patterns 23a and 23b except for side surfaces facing each other.

The insulating plate 21 is made of, for example, a resin. The resin may be a material having low thermal resistance and high insulating properties. Examples of such a resin include a thermosetting resin. The thermosetting resin may further contain a filler. The thermal resistance of the insulating plate 21 may be reduced by controlling the material and content of the filler. Further, depending on the filler, the linear expansion coefficient of the insulating plate 21 may be made substantially equal to the linear expansion coefficients of the metal plate 22 and the conductive patterns 23a and 23b described later. With such a small difference in linear expansion coefficient, the insulated circuit board 20 is able to reduce the occurrence of warpage due to the difference in linear expansion coefficient even when the temperature changes.

For example, such a thermosetting resin include at least one of an epoxy resin, a cyanate resin, a polyimide resin, a benzoxazine resin, an unsaturated polyester resin, a phenol resin, a melamine resin, a silicone resin, a maleimide resin, an acrylic resin, and a polyamide resin. The filler is made of at least one of an oxide and a nitride. Examples of the oxide include silicon oxide and aluminum oxide. Examples of the nitride include silicon nitride, aluminum nitride, and boron nitride. Further, hexagonal boron nitride may be used as the filler.

The insulating plate 21 may be a ceramic substrate instead of a resin. The ceramic substrate is made of a ceramic material with high thermal conductivity. The ceramic material contains, for example, aluminum oxide, aluminum nitride, or silicon nitride as a main component. For example, a direct copper bonding (DCB) substrate or an active metal brazed (AMB) substrate may be used as the insulated circuit board 20 including the insulating plate 21 having such a composition.

In the present embodiment, the insulating plate 21 is made of resin, and the difference between the linear expansion coefficient of the insulating plate 21 and the linear expansion coefficients of the metal plate 22 and the conductive patterns 23a and 23b is small.

The metal plate 22 is made of a metal having excellent thermal conductivity. Examples of such a material include copper, aluminum, and an alloy containing at least one of them. Here, copper is contained. In addition, in order to improve corrosion resistance, a plating treatment may be performed on the surface of the metal plate 22. The plating material in this case contains nickel. Examples of such a plating material include nickel, a nickel-phosphorus alloy, and a nickel-boron alloy. The lower surface 22a (first lower surface) of the metal plate 22 also serves as the lower surface of the insulated circuit board 20. The lower surface 22a of the metal plate 22 is located above the lower surface 35a of the sealing member 35, and is entirely exposed from the sealing member 35. That is, the lower surface 35a of the sealing member 35 is located below the lower surface 22a of the metal plate 22. The lower surface 22a of the metal plate 22 and the lower surface 35a of the sealing member 35 are substantially parallel to each other. In the case where the insulating plate 21 is made of resin, the thickness of the metal plate 22 may be 3 times or more and 15 times or less the thickness of the insulating plate 21.

The semiconductor chips 10a and 10b and the semiconductor chips 10d and 10e are disposed on the conductive patterns 23a and 23b, respectively. The conductive patterns 23a and 23b are formed over the entire surface of the insulating plate 21 except for the edge portions thereof. Preferably, in plan view, the edges of the conductive patterns 23a and 23b facing the outer periphery of the insulating plate 21 may overlap the outer peripheral edges of the metal plate 22. In this case, the insulated circuit board 20 maintains the stress balance between the conductive patterns 23a and 23b on the upper surface of the insulating plate 21 and the metal plate 22 on the lower surface of the insulating plate 21. This reduces a risk of damage such as excessive warpage and cracking of the insulating plate 21.

The conductive patterns 23a and 23b are made of a material having excellent electrical conductivity. Examples of such a material include copper, aluminum, and an alloy containing at least one of them. The conductive patterns 23a and 23b may be plated with a material having excellent corrosion resistance. Examples of such a material include nickel, a nickel-phosphorus alloy, and a nickel-boron alloy. The conductive patterns 23a and 23b on the insulating plate 21 are obtained by forming a metal plate on the upper surface of the insulating plate 21 and performing processing such as etching on the metal plate. Alternatively, the conductive patterns 23a and 23b cut out from a metal plate in advance may be bonded to the upper surface of the insulating plate 21. The conductive patterns 23a and 23b included in the semiconductor device 1 are merely examples. The number, shapes, sizes, and the like of the conductive patterns may be appropriately selected as needed.

The printed board 30 includes an insulating layer and a plurality of upper circuit pattern layers formed on the upper surface of the insulating layer. The printed board 30 may include a plurality of lower circuit pattern layers on the lower surface of the insulating layer. The printed board 30 faces the upper surface of the insulated circuit board 20. The printed board 30 is electrically connected to the output electrodes, the input electrodes, and the control electrodes of the semiconductor chips 10a, 10b, 10d, and 10e. Implant pins 31a, 31b, 31d, and 31e illustrated in FIG. 2 are merely examples, and other implant pins that are not illustrated in FIG. 2 may further be provided. The upper portions of the implant pins 31a, 31b, 31d, and 31e and implant pins not illustrated are electrically connected to the upper circuit pattern layers and lower circuit pattern layers of the printed board 30, and the lower portions thereof are connected to the output electrodes and control electrodes of the semiconductor chips 10a, 10b, 10d, and 10e by the solder 32.

For example, the printed board 30 is electrically connected to the output electrodes on the upper surfaces of the semiconductor chips 10a and 10b through the implant pins 31a and 31b. The printed board 30 is also electrically connected to the output electrodes on the upper surfaces of the semiconductor chips 10d and 10e through the implant pins 31d and 31e.

The printed board 30 is electrically connected to the input electrodes on the lower surfaces of the semiconductor chips 10a and 10b via an implant pin 31c and the conductive pattern 23a. Further, the printed board 30 is electrically connected to the input electrodes on the lower surfaces of the semiconductor chips 10d and 10e via an implant pin 31f and the conductive pattern 23b.

The printed board 30 is electrically connected to the control electrodes of the semiconductor chips 10a and 10d via implant pins (not illustrated). The printed board 30 is also electrically connected to the control electrodes of the semiconductor chips 10b and 10e via implant pins (not illustrated).

The semiconductor unit 25 includes the above-described semiconductor chips 10a, 10b, 10d, and 10e, insulated circuit board 20, and printed board 30. The semiconductor unit 25 is not limited to the configuration illustrated in FIG. 2 (and FIG. 7) as long as it has a circuit configuration to achieve a desired function.

The sealing member 35 seals the insulated circuit board 20, the semiconductor chips 10a, 10b, 10d, and 10e, the solders 12 and 32, the printed board 30, and the implant pins 31a, 31b, 31c, 31d, 31e, and 31f as a whole. The sealing member 35 has a rectangular parallelepiped shape and includes the lower surface 35a and the upper surface 35b. The lower surface 35a and the upper surface 35b have the same shape, and have a rectangular shape in plan view. The sealing member 35 further includes side surfaces 35c1, 35c2, 35c3, and 35c4 surrounding the four sides of each of the lower surface 35a and the upper surface 35b in order. The side surfaces 35cl and 35c3 extend along the long-side direction (±X direction) of the sealing member 35, and the side surfaces 35c2 and 35c4 extend along the short-side direction (±Y direction) of the sealing member 35. The side surfaces 35c1, 35c2, 35c3, and 35c4 are each connected to the lower surface 35a and the upper surface 35b. The side surfaces 35c1, 35c2, 35c3, and 35c4 are also connected to one another. Each of their connection points may be R-chamfered or C-chamfered.

The lower surface 35a of the sealing member 35 is located below the lower surface 22a of the insulated circuit board 20. The lower surface 35a of the sealing member 35 is open to expose the entire lower surface 22a of the insulated circuit board 20, and includes a space (i.e., under-board space) 35e below the lower surface 22a. The space 35e has the same shape and same size as the lower surface 22a of the insulated circuit board 20 in plan view. The thickness (height) of the space 35e is the height of the gap between the lower surface 22a of the insulated circuit board 20 and the lower surface 35a of the sealing member 35. That is, as illustrated in FIG. 2, the space 35e is the gap between the lower surface 22a of the insulated circuit board 20 and the cooling surface 3a of the cooling module 3.

Further, in the sealing member 35, a lateral space 35f that is continuous with the space 35e is formed on a side of the space 35e. The lateral space 35f may be formed on any side of the space 35e. In the present embodiment, as an example, lateral spaces 35f are formed to surround the four sides of the space 35e and extend outward from all the sides. In this case, the four lateral spaces 35f surrounding the four sides may be continuous with one another.

The upper portion of the lateral spaces 35f is defined by inclined surfaces 35f1, 35f2, 35f3, and 35f4 (FIG. 4 illustrates the inclined surface 35f2) that are inclined downward from the space 35e toward the sides (outer sides) of the space 35e. The upper end sides 35g1, 35g2, 35g3, and 35g4 of the inclined surfaces 35f1, 35f2, 35f3, and 35f4 are connected to respective sides of the lower surface 22a of the insulated circuit board 20, and the lower end sides 35h1, 35h2, 35h3, and 35h4 of the inclined surfaces 35f1, 35f2, 35f3, and 35f4 are connected to the lower surface 35a of the sealing member 35.

That is, the sealing member 35 has a storage region 35d including the space 35e and the lateral spaces 35f as an opening in the lower surface 35a. The storage region 35d has a truncated quadrangular pyramid shape surrounded by the lower surface 22a of the insulated circuit board 20, the region surrounded by the lower end sides of the inclined surfaces 35f1, 35f2, 35f3, and 35f4, and the inclined surfaces 35f1, 35f2, 35f3, and 35f4.

The angles of the inclined surfaces 35f1, 35f2, 35f3, and 35f4 with respect to the lower surface 35a of the sealing member 35 may be smaller than 45°. The lower surface 22a of the insulated circuit board 20 is exposed to the space 35e without protruding from the upper end sides 35g1, 35g2, 35g3, and 35g4 of the inclined surfaces 35f1, 35f2, 35f3, and 35f4 toward the space 35e.

Further, the lower end sides 35h1, 35h2, 35h3, and 35h4 of the inclined surfaces 35f1, 35f2, 35f3, and 35f4 may be located at positions that allow the lateral spaces 35f to have a predetermined volume. As described later, the adhesive member 4 spreads in the lateral spaces 35f. For this case, the lateral spaces 35f are formed to have a volume capable of reliably accommodating the spread adhesive member 4. For example, it is desirable that the lower end sides 35h1, 35h2, 35h3, and 35h4 of the inclined surfaces 35f1, 35f2, 35f3, and 35f4 be separated from the corresponding sides of the space 35e by at least the height of the space 35e. In the present embodiment, the storage region 35d has a rectangular shape in plan view. Corner portions of the storage region 35d may be R-chamfered or C-chamfered.

The sealing member 35 may be a thermosetting resin containing a filler. That is, the sealing member 35 is made mainly of an insulating filler and a resin (thermosetting resin) which will be described later. In this case, the thermosetting resin is, for example, an epoxy resin, a phenol resin, a maleimide resin, or a polyester resin. The filler may contain, as a main component, an insulating ceramic having high thermal conductivity. Such fillers are, for example, silicon oxide, aluminum oxide, boron nitride or aluminum nitride. The content of the filler is 10% by volume or more and 70% by volume or less with respect to the entire sealing member 35.

In the above semiconductor module 2, the adhesive member 4 is provided on the lower surface 22a of the insulated circuit board 20 in the space 35e. In the semiconductor device 1, the cooling module 3 is attached to the lower surface 35a of the semiconductor module 2 via the adhesive member 4.

The adhesive member 4 is provided in the space 35e between the lower surface 22a of the insulated circuit board 20 of the semiconductor module 2 and the cooling surface 3a of the cooling module 3, to bond the lower surface 22a of the insulated circuit board 20 of the semiconductor module 2 to the cooling surface 3a of the cooling module 3. Thus, the adhesive member 4 fixes the semiconductor module 2 to the cooling module 3, and also thermally connects the metal plate 22 to the cooling module 3. The adhesive member 4 may be in contact with at least the entire lower surface 22a of the metal plate 22 of the semiconductor module 2. The adhesive member 4 illustrated in FIG. 4 is in contact with the entire lower surface 22a of the metal plate 22 of the semiconductor module 2, and further protrudes into the lateral space 35f.

The adhesive member 4 is an organic resin adhesive containing a thermosetting resin as a main component, and contains a conductive filler (not illustrated). Examples of the thermosetting resin include an epoxy resin, a phenol resin, and a polyimide resin. Here, an epoxy resin is used.

The filler of the adhesive member 4 may contain a conductive metal. Examples of the metal include silver, copper, gold, nickel, chromium, aluminum, and an alloy containing at least one of these metals. The filler may have, for example, a spherical shape or a flake shape. The filler may mainly contain such a metal, and may contain an inorganic filler in addition to the metal. Examples of such an inorganic filler include ceramics having high insulation and high thermal conductivity. For example, the ceramics include at least one of aluminum oxide, aluminum nitride, silicon nitride, and boron nitride.

The filler in the adhesive member 4 may connect the lower surface 22a of the metal plate 22 and the cooling surface 3a of the cooling module 3. That is, the filler forms a thermal path between the lower surface 22a of the metal plate 22 and the cooling surface 3a of the cooling module 3. This improves the thermal conductivity from the metal plate 22 to the cooling module 3. The filler may include a sintered body in the adhesive member 4. Since the adhesive member 4 needs to have low thermal resistivity (high thermal conductivity), the adhesive member 4 needs to be as thin as possible. However, if the adhesive member 4 has a thickness of less than 50 μm, the stress of the adhesive member 4 increases. The thickness may be, for example, 50 μm or more and 300 μm or less. Instead of the adhesive member 4, a thermally conductive material having no adhesiveness may be used. Examples of the thermally conductive material in this case include thermally conductive grease, elastomer sheet, room temperature vulcanization (RTV) rubber, gel, and phase change material.

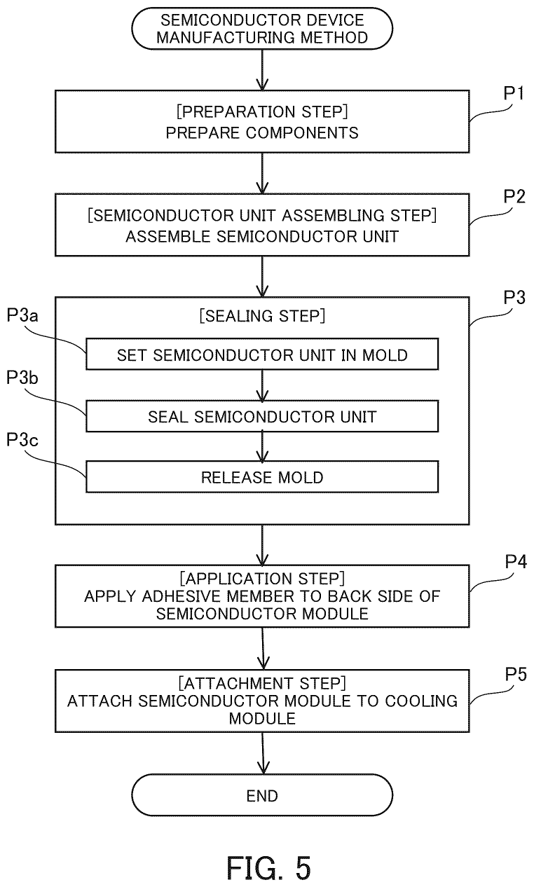

Next, a method of manufacturing the semiconductor device 1 illustrated in FIGS. 1 and 2 will be described with reference to FIG. 5. FIG. 5 is a flowchart illustrating a semiconductor device manufacturing method according to the first embodiment. First, a preparation step of preparing components of the semiconductor device 1 is performed (step P1). The components prepared here include, for example, the semiconductor chips 10a, 10b, 10d, and 10e, the insulated circuit board 20, the printed board 30 with the implant pins 31a, 31b, 31c, 31d, 31e, and 31f, and the sealing member 35, which form the semiconductor module 2. The cooling module 3 is also prepared. Although not listed here, any other components to be used for manufacturing the semiconductor device 1 may be prepared. A manufacturing apparatus to be used for manufacturing the semiconductor device 1 may also be prepared. Examples of the manufacturing apparatus include an application apparatus for applying solder and a molding apparatus for sealing with a sealing member.

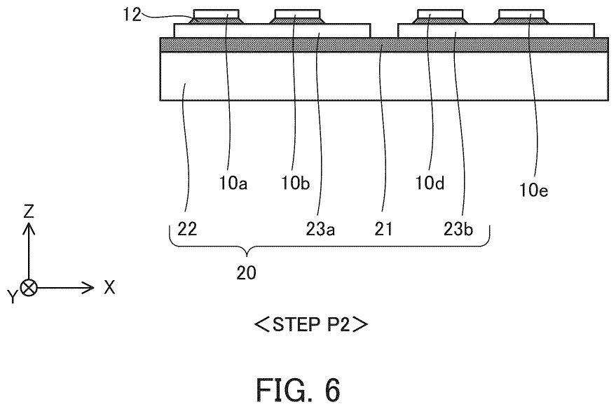

Next, a semiconductor unit assembling step of assembling the semiconductor unit 25 is performed (step P2). This semiconductor unit assembling step will be described with reference to FIGS. 6 and 7. FIG. 6 is a first view for describing the semiconductor unit assembling step of the semiconductor device manufacturing method according to the first embodiment. FIG. 7 is a second view for describing the semiconductor unit assembling step of the semiconductor device manufacturing method according to the first embodiment. FIGS. 6 and 7 correspond to the cross section of FIG. 2.

The semiconductor chips 10a, 10b, 10d, and 10e are bonded to the conductive patterns 23a and 23b of the insulated circuit board 20 via the solder 12. At this time, conventional solder bonding is performed. As a result, as illustrated in FIG. 6, a structure is obtained in which the semiconductor chips 10a and 10b are bonded to the conductive pattern 23a of the insulated circuit board 20 via the solder 12, and the semiconductor chips 10d and 10e are bonded to the conductive pattern 23b via the solder 12.

Thereafter, the implant pins 31a, 31b, 31c, 31d, 31e, and 31f of the printed board 30 are bonded to the semiconductor chips 10a and 10b, the conductive pattern 23a of the insulated circuit board 20, the semiconductor chips 10d and 10e, and the conductive pattern 23b of the insulated circuit board 20.

The implant pins 31a, 31b, 31c, 31d, 31e, and 31f are provided on the printed board 30 in advance. Such implant pins 31a, 31b, 31c, 31d, 31e, 31f are bonded by conventional solder bonding. Thus, as illustrated in FIG. 7, the printed board 30 is attached to the insulated circuit board 20 to which the semiconductor chips 10a, 10b, 10d, and 10e are bonded, so that the semiconductor unit 25 is obtained.

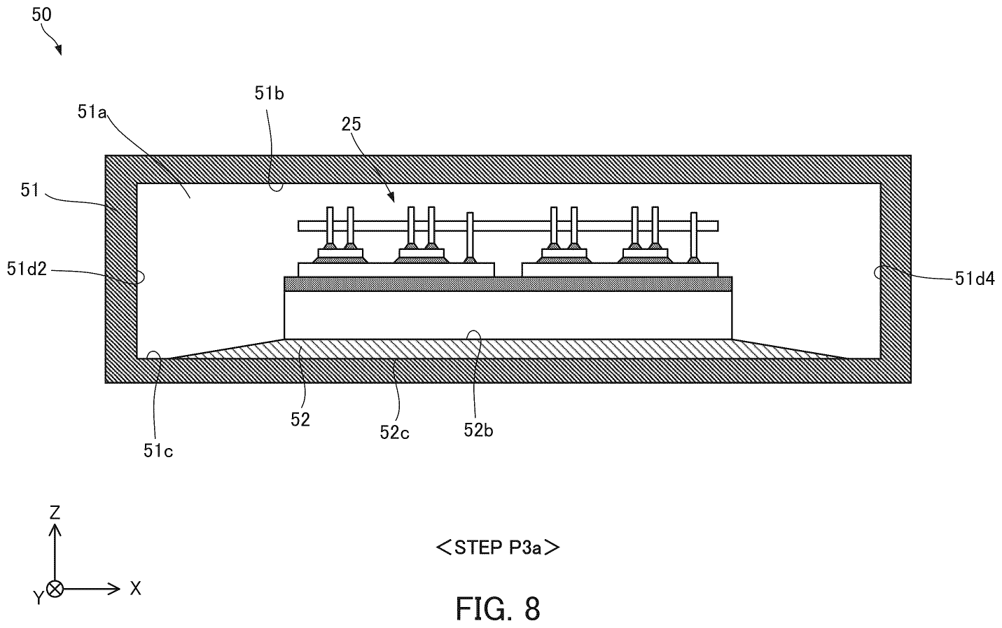

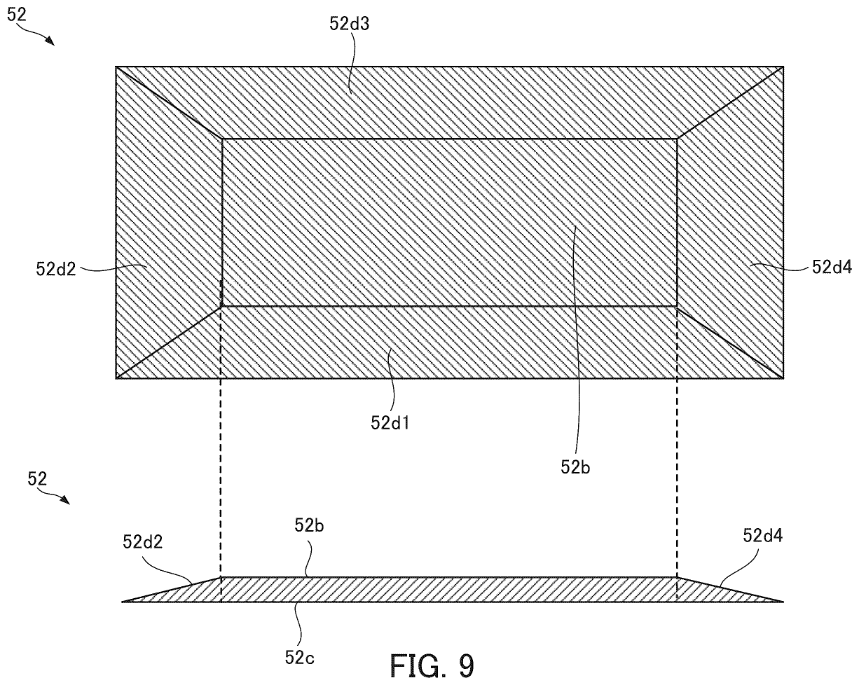

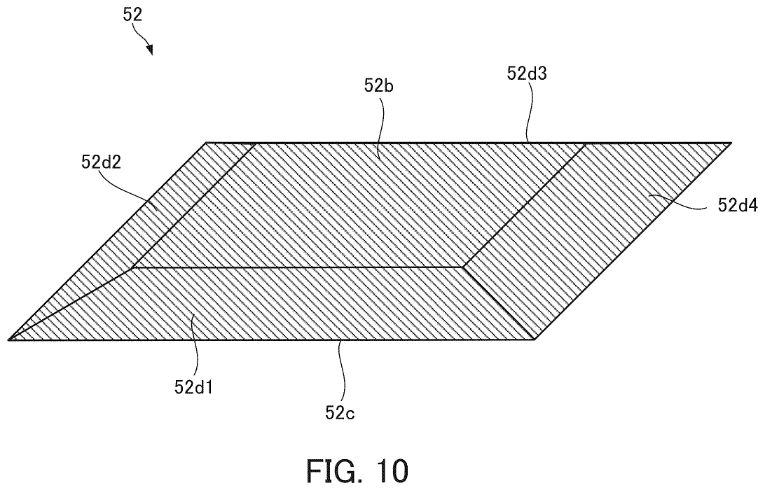

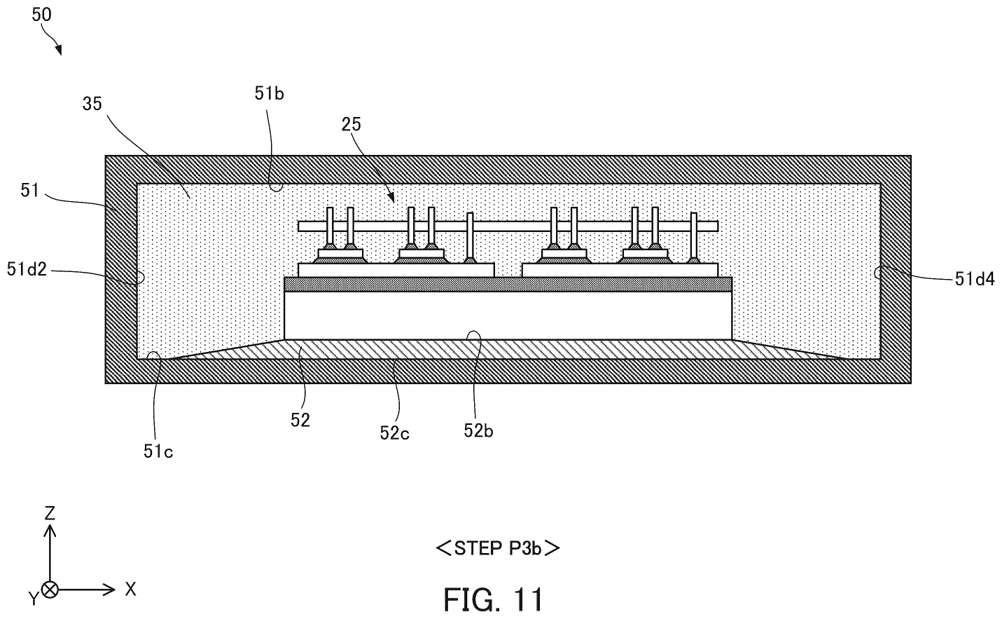

Next, a sealing step of sealing the semiconductor unit 25 is performed (step P3). The sealing step will be described with reference to FIGS. 8 to 13. FIG. 8 is a first view for describing the sealing step of the semiconductor device manufacturing method according to the first embodiment. FIG. 9 illustrates a storage mold to be used in the sealing step of the semiconductor device manufacturing method according to the first embodiment. FIG. 10 is a perspective view of the storage mold to be used in the sealing step of the semiconductor device manufacturing method according to the first embodiment. The upper part of FIG. 9 is a plan view of a storage portion 52, and the lower part is a side view of the storage portion 52. FIGS. 11 to 13 are second to fourth views for describing the sealing step of the semiconductor device manufacturing method according to the first embodiment.

The sealing step P3 includes the following steps. First, the semiconductor unit 25 obtained in step P2 is set in, for example, a mold 50 illustrated in FIG. 8 (step P3a). The mold 50 includes an enclosure portion 51 and a storage portion 52. The mold 50 is made of a material having heat resistance and a small thermal expansion coefficient. Examples of such a material include steel. Examples of the steel material include stainless steel. A material having high releasability from the sealing member 35 may be applied to the inner surface of the mold 50.

The enclosure portion 51 has a box shape, and a cavity 51a is surrounded by an upper surface 51b, a lower surface 51c, and sealing surfaces (sealing surfaces 51d2 and 51d4 are illustrated in FIG. 8) that sequentially surround the four sides of each of the upper surface 51b and the lower surface 51c. The shape of the cavity 51a corresponds to that of the sealing member 35 of the semiconductor module 2. A gate (not illustrated) into which a sealing material as a raw material of the sealing member 35 is injected may be formed in any of the surfaces of the enclosure portion 51. Although details of the enclosure portion 51 are omitted, for example, a lid including the upper surface 51b may be provided so as to be openable and closable. When the semiconductor unit 25 is housed in the enclosure portion 51, the lid is opened. After the semiconductor unit 25 is housed, the lid is closed. Such a function of housing the semiconductor unit 25 in the enclosure portion 51 is an example, and another mechanism may be used.

The storage portion 52 is provided on the lower surface 51c of the enclosure portion 51. The storage portion 52 may be formed integrally with the lower surface 51c of the enclosure portion 51. The storage portion 52 and the enclosure portion 51 may be made of the same material. The storage portion 52 has a shape obtained by combining the space 35e and the lateral spaces 35f of the semiconductor module 2. Such a shape may be, for example, a truncated quadrangular pyramid shape. Specifically, as illustrated in FIGS. 9 and 10, the storage portion 52 includes a sealing upper surface 52b, a lower surface 52c, and sealing side surfaces 52d1, 52d2, 52d3, and 52d4 surrounding the four sides of each of the sealing upper surface 52b and the lower surface 52c in order. The sealing upper surface 52b has the same size and same shape as the lower surface 22a of the insulated circuit board 20. The angles of the sealing side surfaces 52d1, 52d2, 52d3, and 52d4 with respect to the lower surface 52c may be smaller than 45°.

The semiconductor unit 25 is disposed on the sealing upper surface 52b of the storage portion 52 in the enclosure portion 51 of the mold 50 having such a configuration (see FIG. 8). In this manner, the semiconductor unit 25 is set in the cavity 51a of the mold 50 and housed in the mold 50.

Next, the cavity 51a of the mold 50 in which the semiconductor unit 25 is accommodated in step P3a is filled with a sealing material to seal the semiconductor unit 25 (step P3b). At this time, the mold 50 is maintained in a heated state, and the molten sealing material is injected. When the cavity 51a is entirely filled with the sealing material, the heating of the mold 50 is stopped, the mold 50 is cooled, and the sealing material is solidified. Thus, as illustrated in FIG. 11, the semiconductor unit 25 is sealed by the sealing member 35 in the mold 50.

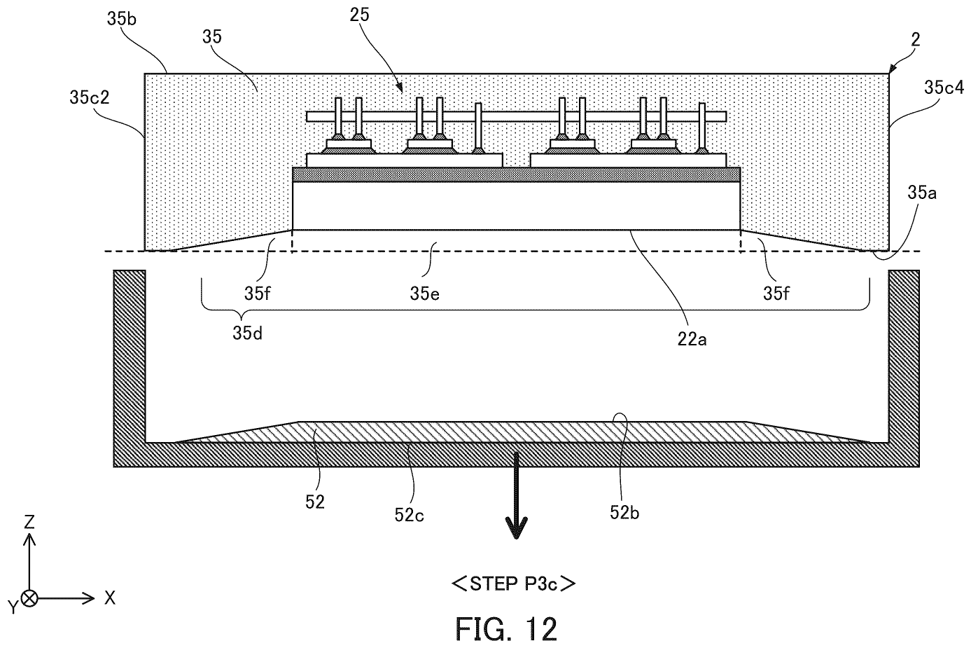

Next, the mold 50 is released from the semiconductor unit 25 sealed with the sealing member 35 in step P3b (step P3c). For example, the lid including the upper surface 51b of the enclosure portion 51 of the mold 50 is removed, and the mold 50 is released from the semiconductor module 2 in which the semiconductor unit 25 is sealed with the sealing member 35. Specifically, as illustrated in FIG. 12, the mold 50 is released in the −Z direction. The sealing side surfaces 52d1, 52d2, 52d3, and 52d4 of the storage portion 52 are connected to the sealing upper surface 52b at obtuse angles. Therefore, when the mold 50 is released from the semiconductor module 2, the storage portion 52 is also easily released from the sealing member 35.

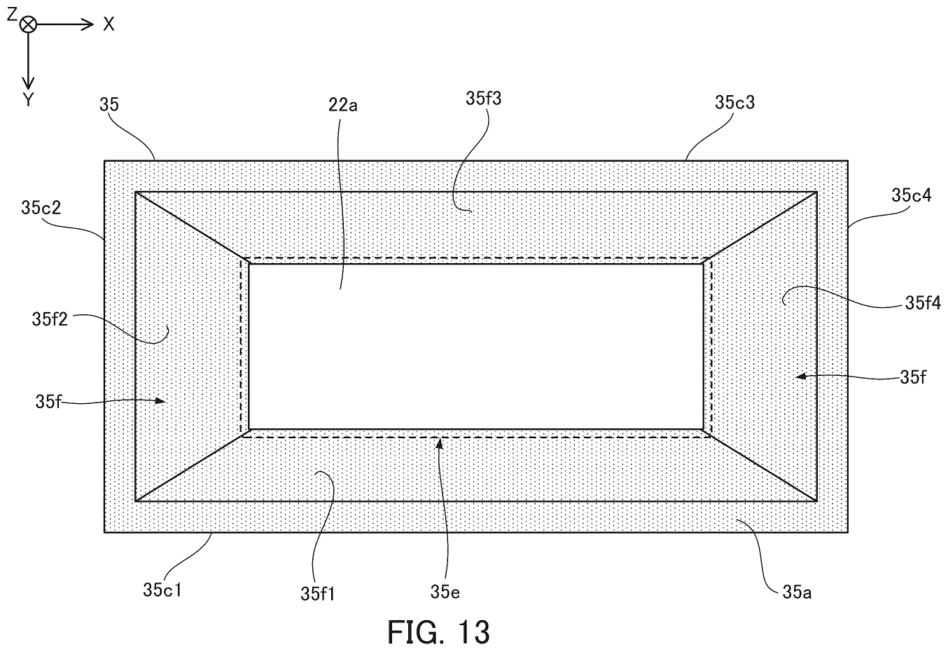

Thus, the semiconductor module 2 is obtained. On the lower surface 35a side of thus obtained semiconductor module 2, as illustrated in FIG. 13, the space 35e is formed in the central portion, and the lateral spaces 35f are formed around the space 35e. The lower surface 22a of the insulated circuit board 20 is exposed from the space 35e of the semiconductor module 2.

Next, an application step of applying an adhesive member to the back side of the semiconductor module 2 is performed (step P4). The adhesive member 4 is applied to the entire lower surface 22a of the insulated circuit board 20 exposed from the space 35e of the semiconductor module 2. The adhesive member 4 applied at this time may have a thickness exceeding the distance between the lower surface 22a of the insulated circuit board 20 and the lower surface 35a of the sealing member 35, for example. The adhesive member 4 may be applied not to the semiconductor module 2 but to the cooling surface 3a of the cooling module 3.

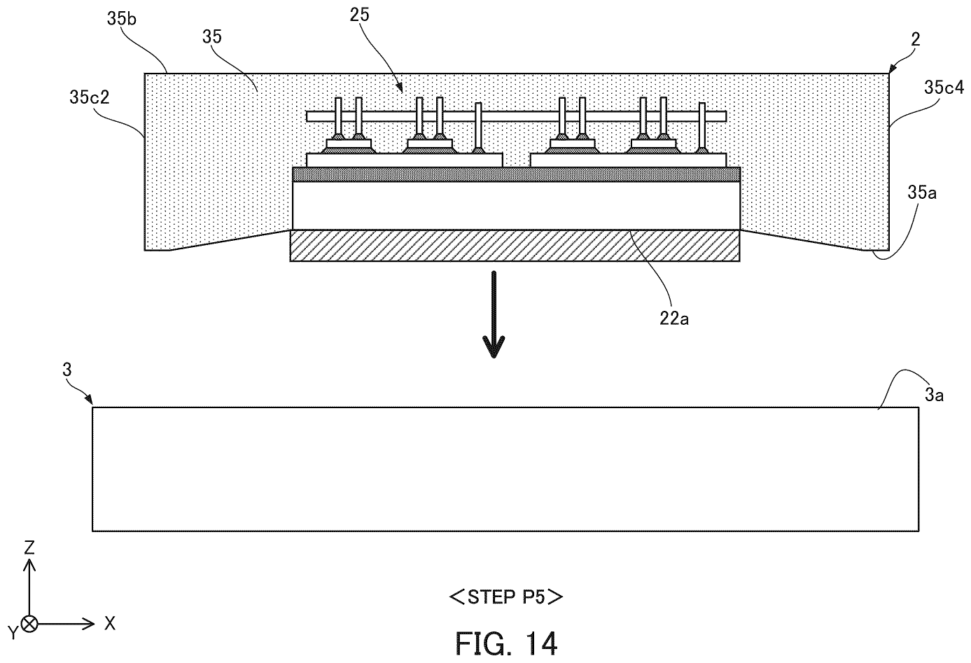

Next, an attachment step (bonding step) of attaching the semiconductor module 2 to the cooling module 3 is performed (step P5). The attachment step will be described with reference to FIG. 14. FIG. 14 is a view for describing the attachment step of the semiconductor device manufacturing method according to the first embodiment.

As illustrated in FIG. 14, the semiconductor module 2 to which the adhesive member 4 is applied in step P4 is disposed on the cooling surface 3a of the cooling module 3. By doing so, the adhesive member 4 is sandwiched between the lower surface 22a of the insulated circuit board 20 and the cooling surface 3a of the cooling module 3, and a part of the adhesive member 4 spreads outward from the space 35e. In the semiconductor module 2, the lateral spaces 35f are formed on the four sides of the space 35e. Therefore, the adhesive member 4 spread to the sides of the space 35e is accommodated in the lateral spaces 35f (for example, see FIG. 4). Therefore, in the semiconductor device 1, even when the semiconductor module 2 and the cooling module 3 are joined, leakage of the adhesive member 4 to the outside from between the lower surface 35a of the semiconductor module 2 and the cooling surface 3a of the cooling module 3 is prevented.

As described above, the semiconductor device 1 in which the cooling module 3 is attached to the semiconductor module 2 is obtained through the semiconductor device manufacturing process illustrated in FIG. 5. The configuration of the semiconductor device 1 is an example, and in particular, the semiconductor unit 25 may have another structure.

The above-described semiconductor device 1 includes the semiconductor module 2 including the insulated circuit board 20 having the lower surface 22a, and the sealing member 35 sealing the upper surface and the side surfaces of the insulated circuit board 20, having the lower surface 35a located below the lower surface 22a of the insulated circuit board 20, the lower surface 35a being open to expose the entire lower surface 22a, and including the space 35e below the lower surface 22a. Further, in the sealing member 35, the lateral spaces 35f that are continuous with the space 35e is formed on the sides of the space 35e, and the upper portions of the lateral spaces 35f are defined by the inclined surfaces 35f1, 35f2, 35f3, and 35f4 inclined downward from the space 35e toward the sides of the space 35e. When this semiconductor module 2 is attached to the cooling surface 3a of the cooling module 3 via the adhesive member 4 provided on the lower surface 22a of the insulated circuit board 20, the adhesive member 4 is accommodated in the lateral spaces 35f even if the adhesive member 4 spreads. Therefore, in the semiconductor device 1, leakage of the adhesive member 4 to the outside from between the lower surface 35a of the semiconductor module 2 and the cooling surface 3a of the cooling module 3 is prevented.

For example, if the semiconductor module 2 does not include the lateral spaces 35f, the adhesive member 4 sandwiched between the lower surface 22a of the insulated circuit board 20 of the semiconductor module 2 and the cooling surface 3a of the cooling module 3 may leak out of the semiconductor device 1 through the gap between the lower surface 35a of the semiconductor module 2 (sealing member 35) and the cooling surface 3a. If the adhesive member 4 leaks out, the adhesive member 4 adheres to the periphery of the semiconductor device 1. In the case where the filler of the adhesive member 4 is a conductive metal, the leaked adhesive member 4 adheres to the side surfaces of the semiconductor module 2, which reduces the insulation distance and thus reduces the insulation property. If the insulation is not maintained, the reliability of the semiconductor device 1 decreases.

By contrast, the semiconductor module 2 of the present embodiment includes the lateral spaces 35f and the adhesive member 4 is prevented from leaking. Therefore, the adhesive member 4 may contain a filler made of a conductive metal. This improves the thermal conductivity of the adhesive member 4 and also improves the heat dissipation of the semiconductor device 1.

The adhesive member 4 may be applied so as to fill the space 35e and the lateral spaces 35f when the semiconductor module 2 is attached to the cooling surface 3a of the cooling module 3. In this case, the upper surface of the adhesive member 4 extends at an angle smaller than 450 from the outer edge of the lower surface 22a of the insulated circuit board 20. By applying the adhesive member 4 in this manner, heat from the lower surface 22a of the insulated circuit board 20 is conducted through the adhesive member 4 by 45° diffusion. As compared with the case where only the space 35e is provided, the formation of the lateral spaces 35f increases an area that accommodates the adhesive member 4, which improves the heat dissipation of the semiconductor device 1.

### Second Embodiment

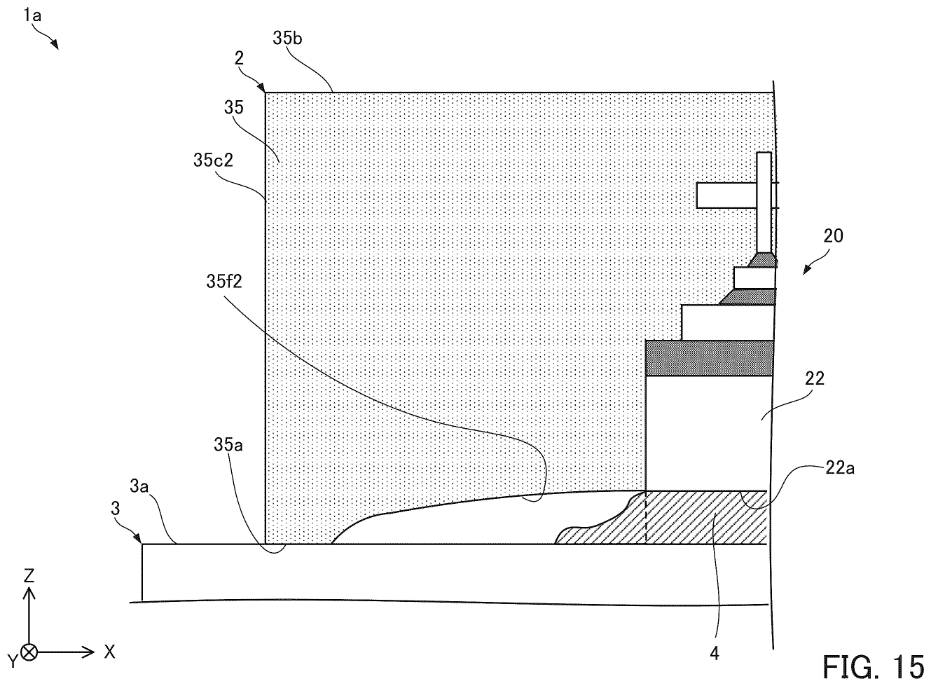

A semiconductor device according to a second embodiment will be described with reference to FIG. 15. FIG. 15 is an enlarged view of a first cross section of the semiconductor device according to the second embodiment. FIG. 15 is an enlarged sectional view, corresponding to FIG. 4, of the semiconductor device 1a according to the second embodiment.

In the semiconductor device 1a of the second embodiment, the inclined surfaces 35f1, 35f2, 35f3, and 35f4 of the lateral spaces 35f included in the semiconductor module 2 include portions curved from the inside toward the outside. The semiconductor device 1a of the second embodiment has the same configuration as that of the semiconductor device 1 of the first embodiment except for the inclined surfaces 35f1, 35f2, 35f3, and 35f4 of the lateral spaces 35f.

For example, the inclined surface 35f2 of the lateral space 35f illustrated in FIG. 15 is inclined downward from the space 35e (the edge of the lower surface 22a of the insulated circuit board 20) toward the side of the space 35e (−X direction), is curved in the middle, and extends to the lower surface 35a.

The adhesive member 4 may spread from the space 35e to the lateral spaces 35f, and the lateral spaces 35f may be filled with the adhesive member 4. In this case, since the inclined surface 35f2 includes the curved portion, the adhesive member 4 sufficiently spread in the lateral spaces 35f. This reduces a risk of generation of voids in the lateral spaces 35f filled with the adhesive member 4. Therefore, in the semiconductor device 1a, even if the lateral spaces 35f are filled with the adhesive member 4 spreading from the space 35e, the occurrence of voids is suppressed, and thus a decrease in heat dissipation is prevented.

For example, in the case where the curved portion of the inclined surface 35f2 is located above the lower surface 22a of the insulated circuit board 20, the mold 50 is not easy to be released when the mold 50 is released (step P3c) in the sealing step (step P3). Therefore, the inclined surface 35f2 of the lateral space 35f is preferably inclined downward from the space 35e (the edge of the lower surface 22a of the insulated circuit board 20) toward the side (−X direction) even when the inclined surface 35f2 is curved in the middle.

### Third Embodiment

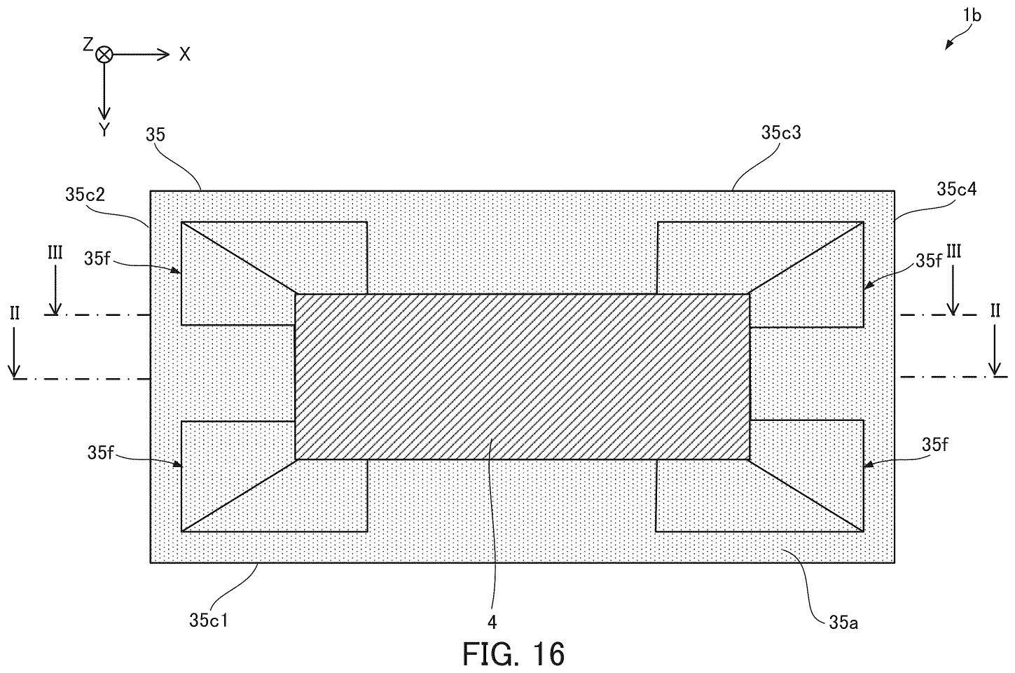

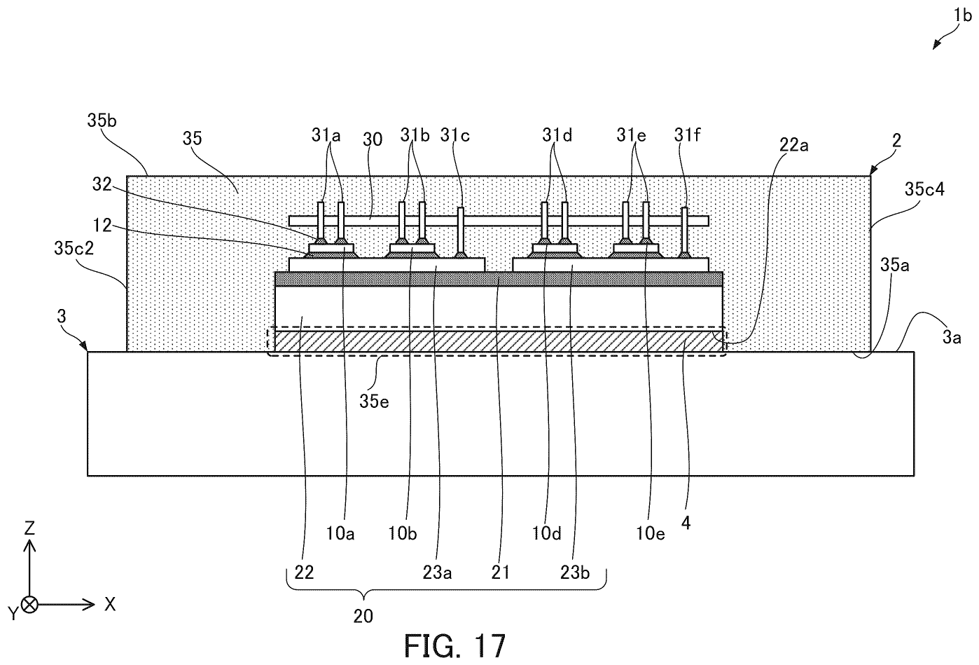

A third embodiment provides a case where lateral spaces 35f are provided at corner portions of the space 35e in plan view. The semiconductor device according to the third embodiment will be described with reference to FIGS. 16 and 17. FIG. 16 is a second sectional view of the semiconductor device according to the third embodiment. FIG. 17 is a third sectional view of the semiconductor device according to the third embodiment. The sectional view of the semiconductor device 1b according to the third embodiment, illustrated in FIG. 16, corresponds to that illustrated in FIG. 3. FIG. 17 illustrates a cross section taken along a dashed-dotted line II-II in FIG. 16. Please refer to FIG. 2 for the cross section taken along the dashed-dotted line III-III in FIG. 16, as the cross section corresponds to the cross section of the semiconductor module 2 in FIG. 2.

In the sealing member 35 included in the semiconductor module 2 of the semiconductor device 1b of the third embodiment, as illustrated in FIGS. 16 and 2, the lateral spaces 35f are formed on the sides of the corner portions of the space 35e corresponding to the corners of the lower surface 22a of an insulated circuit board 20 in plan view. As illustrated in FIG. 16, each lateral space 35f is preferably formed so as to include the corresponding corner of the space 35e in plan view. However, the lateral spaces 35f may be formed so as to be continuous with the corners of the space 35e, and a lateral space 35f may be formed on only one side of two sides constituting a corner of the space 35e in plan view. In addition, in the semiconductor module 2, as illustrated in FIG. 17, regions in which the lateral spaces 35f are not formed, excluding the corners of the space 35e in plan view, are surrounded by the sealing member 35.

Each lateral space 35f of the third embodiment may also have an inclined surface (reference numeral omitted) inclined downward from the space 35e toward a side (outer side), in the upper portion thereof. Although FIG. 16 merely illustrates a case where each lateral space 35f has a rectangular shape in plan view, each lateral space 35f may have a shape other than a rectangular shape. The corners of the lateral space 35f may be rounded in plan view.

In the above semiconductor device 1b, the semiconductor module 2 to which the adhesive member 4 is applied is disposed on the cooling surface 3a of the cooling module 3, and the spread adhesive member 4 flows into the lateral spaces 35f continuous with the corner portions of the space 35e. Therefore, as in the first embodiment, in the semiconductor device 1b, leakage of the adhesive member 4 to the outside from between the lower surface 35a of the semiconductor module 2 and the cooling surface 3a of the cooling module 3 is prevented. FIG. 16 depicts a case where the adhesive member 4 is applied to the entire lower surface 22a of the insulated circuit board 20 of the semiconductor module 2.

Further, the temperature changes in the semiconductor device 1b while the semiconductor chips 10a, 10b, 10d, and 10e operate. When the temperature changes, stress may be generated at corner portions of the insulated circuit board 20 due to a difference in linear expansion coefficient between the components. Therefore, the corner portions of the lower surface 22a of the insulated circuit board 20 are more likely to peel off from the adhesive member 4. When such peeling occurs, a decrease in heat dissipation of the semiconductor device 1b is promoted.

However, in the semiconductor module 2 of the semiconductor device 1b, the lateral spaces 35f are formed so as to include the corner portions of the space 35e in plan view. Therefore, when the semiconductor module 2 to which the adhesive member 4 is applied is attached to the cooling module 3, the spread adhesive member 4 flows from the space 35e into the lateral spaces 35f at the corner portions. This reduces the occurrence of peeling of the corner portions of the lower surface 22a of the insulated circuit board 20 from the adhesive member 4, which result in preventing a decrease in the heat dissipation of the semiconductor device 1b.

In view of the semiconductor devices 1 and 1b of the first and third embodiments, in the semiconductor module 2, it is preferable that the lateral spaces 35f that are continuous with the space 35e are formed at least at the corner portions of the space 35e in plan view.

The disclosed techniques make it possible to prevent leakage of an adhesive member.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
a board having an upper surface, a lower surface, and a side surface; and
a sealing member having a lower surface and an opening in the lower surface thereof, the opening having an inclined side surface therein, the sealing member sealing the upper surface and the side surface of the board, leaving the entire lower surface of the board exposed from the opening, so as to form
an under-board space directly below the lower surface of the board, and
a lateral space directly below the inclined side surface of the opening, and continuous with the under-board space.

2. The semiconductor device according to claim 1, further comprising:
a cooling module having a cooling surface, on which the lower surface of the sealing member is disposed; and
a thermally conductive material provided in the under-board space, between the lower surface of the board and the cooling surface.

3. The semiconductor device according to claim 2, wherein the thermally conductive material is an adhesive member.

4. The semiconductor device according to claim 1, further comprising:
a cooling module having a cooling surface, on which the lower surface of the sealing member is disposed; and
an adhesive member provided in the under-board space and bonding the lower surface of the board to the cooling surface.

5. The semiconductor device according to claim 4, wherein the adhesive member contains a conductive filler.

6. The semiconductor device according to claim 4, wherein the adhesive member has an edge portion extending from the under-board space to the lateral space.

7. The semiconductor device according to claim 1, wherein an angle of the inclined side surface with respect to the lower surface of the sealing member is smaller than 45°.

8. The semiconductor device according to claim 1, wherein
the inclined side surface of the opening is formed along an entire circumcircle of the opening, so that the lateral space fully encircles the under-board space in a plan view of the semiconductor device.

9. The semiconductor device according to claim 1, wherein the inclined side surface of the opening includes a portion curved from an inside toward an outside thereof.

10. The semiconductor device according to claim 1, wherein in a plan view of the semiconductor device,
the lower surface of the board is of a shape having a corner, and
the lateral space is located at a side of the corner.

11. A method of manufacturing a semiconductor device, comprising:
preparing a board having an upper surface, a lower surface and a side surface, and preparing a sealing member;
preparing a mold having:
a sealing upper surface that is identical in size and shape to the lower surface of the board,
a sealing lower surface opposite to the sealing upper surface, and
a sealing side surface provided on a side of the sealing upper surface in a plan view of the semiconductor device and inclined downward from the sealing upper surface;
disposing the lower surface of the board on the sealing upper surface of the mold, and sealing the board and the mold with the sealing member while exposing the sealing lower surface; and
releasing the mold after the sealing member is solidified.

12. The method of manufacturing the semiconductor device according to claim 11, wherein an angle of the sealing side surface with respect to the sealing upper surface is smaller than 45°.

13. The method of manufacturing the semiconductor device according to claim 11, further comprising:
preparing a cooling module having an adhesive member and a cooling surface, and
bonding the exposed lower surface of the board in a storage region, formed in the sealing member by releasing the mold from the sealing member, to the cooling surface of the cooling module with the adhesive member.
